(19) United States
(12) Patent Application Publication
(10) Pub. No.: US 2010/0254174 A1
(43) Pub. Date: Oct. 7, 2010

(54) Resistive Sense Memory with Complementary Programmable Recording Layers

(75) Inventors: Yuankai Zheng, Bloomington, MN (US); Xiaohua Lou, Bloomington, MN (US); Zheng Gao, San Jose, CA (US); Wei Tian, Bloomington, MN (US); Dimitar V. Dimitrov, Edina, MN (US); Dexin Wang, Eden Prairie, MN (US)

Correspondence Address: CAMPBELL NELSON WHIPPS, LLC, HISTORIC HAMM BUILDING, 408 SAINT PETER STREET, SUITE 240, ST. PAUL, MN, 55102, US

(73) Assignee: SEAGATE TECHNOLOGY LLC, Scotts Valley, CA (US)

(21) Appl. No.: 12/416,976

(22) Filed: Apr. 2, 2009

(51) Int. Cl. G11C 11/00; G11C 11/14; G11C 7/00

(52) U.S. Cl. 365/148; 365/171; 365/189.011

(57) ABSTRACT

A resistive sense memory and method of writing data thereto. In accordance with various embodiments, the resistive sense memory comprises a first reference layer with a fixed magnetic orientation in a selected direction coupled to a first tunneling barrier, a second reference layer with a fixed magnetic orientation in the selected direction coupled to a second tunneling barrier, and a recording structure disposed between the first and second tunneling barriers comprising first and second free layers. A selected logic state is written to the resistive sense memory by applying a programming input to impart complementary first and second programmed magnetic orientations to the respective first and second free layers.

### BACKGROUND

Data storage devices generally operate to store and retrieve data in a fast and efficient manner. Some storage devices utilize a semiconductor array of solid-state memory cells to store individual bits of data. Such memory cells can be volatile (e.g., DRAM, SRAM) or non-volatile (RRAM, STRAM, flash, etc.).

As will be appreciated, volatile memory cells generally retain data stored in memory only so long as operational power continues to be supplied to the device, while non-volatile memory cells generally retain data storage in memory even in the absence of the application of operational power.

In these and other types of data storage devices, it is often desirable to increase efficiency of memory cell operation, particularly with regard to the writing of data to the memory cells.

### SUMMARY

Various embodiments of the present invention are generally directed to a resistive sense memory and a method of writing data thereto.

In accordance with various embodiments, the resistive sense memory comprises a first reference layer with a fixed magnetic orientation in a selected direction coupled to a first tunneling barrier, and a second reference layer with a fixed magnetic orientation in the selected direction coupled to a second tunneling barrier. A recording structure is disposed between the first and second tunneling barriers and comprises first and second free layers. A selected logic state is written to the resistive sense memory by applying a programming input to impart complementary first and second programmed magnetic orientations to the respective first and second free layers.

These and other features and advantages which characterize the various embodiments of the present invention can be understood in view of the following detailed discussion and the accompanying drawings.

### BRIEF DESCRIPTION OF THE DRAWINGS

FIG. 1 is a generalized functional representation of an exemplary data storage device constructed and operated in accordance with various embodiments of the present invention.

FIG. 2 generally illustrates a manner in which data are written to a memory cell of the memory array of FIG. 1.

FIG. 3 generally illustrates a manner in which data are read from the memory cell of FIG. 2.

FIG. 4 shows an exemplary construction of a magnetic tunneling junction (MTJ) of a spin-torque transfer random access memory (STRAM) memory cell in accordance with the related art.

FIG. 5 shows a resistive sense memory constructed in accordance with various embodiments of the present invention.

FIG. 6 shows a resistive sense memory having an alternative construction in accordance with various embodiments of the present invention.

FIG. 7 displays an array of resistive sense memory cells operated in accordance with various embodiments of the present invention.

FIG. 8 is a flow diagram for a verify operation performed in accordance with the various embodiments of the present invention.

### DETAILED DESCRIPTION

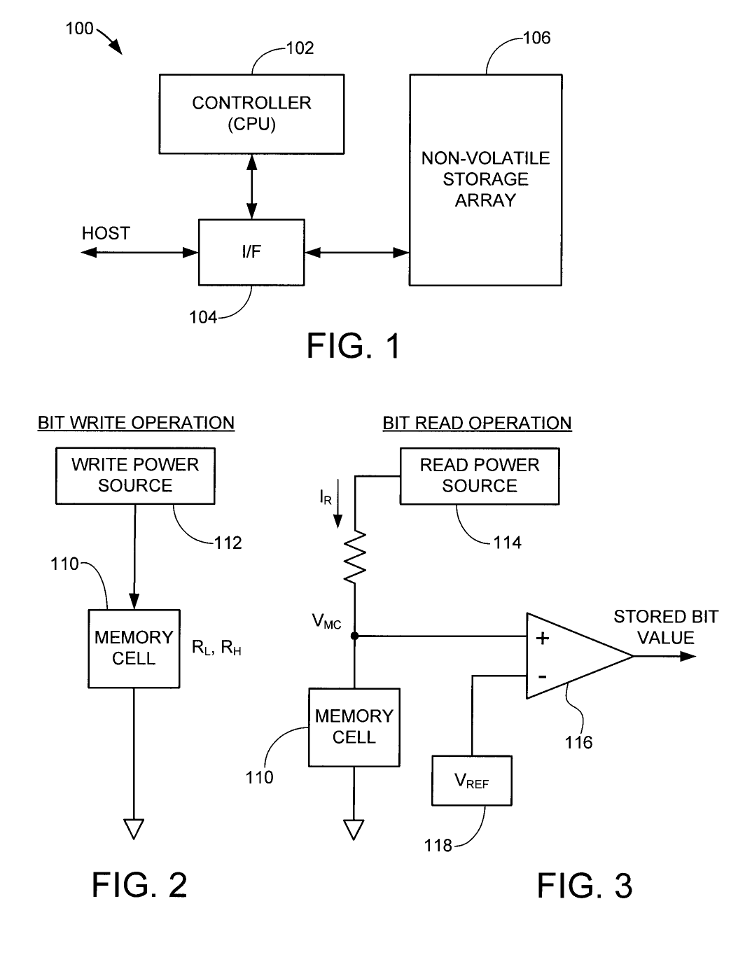

FIG. 1 provides a functional block representation of a data storage device 100 to illustrate an exemplary environment in which various embodiments of the present invention can be advantageously practiced. The device 100 includes a top level controller 102, an interface (I/F) circuit 104 and a non-volatile data storage array 106. The I/F circuit 104 operates under the direction of the controller 102 to transfer user data between the array 106 and a host device (not shown). In some embodiments, the device is characterized as a solid-state drive (SSD), the controller 102 is a programmable microcontroller, and the array 106 comprises an array of nonvolatile memory cells (unit cells).

An exemplary memory cell is shown at 110 in FIG. 2. Data are written to the memory cells 110 using a write power source 112. The source 112 applies a suitable programming input such as in the form of a write voltage and/or current to configure the memory cell 110 to a desired programmed state.

The programmed state can be subsequently read from the memory cell 110 as shown in FIG. 3. A read current is supplied from a suitable read current source 114. A voltage drop across the memory cell V_{MC} is sensed by a sense amplifier 116, and compared to a reference voltage V_{REF} from a voltage reference source 118. The output state of the sense amplifier 116 will nominally reflect the programmed state of the memory cell (e.g., a logical 0, a logical 1, a logical “10,” etc.).

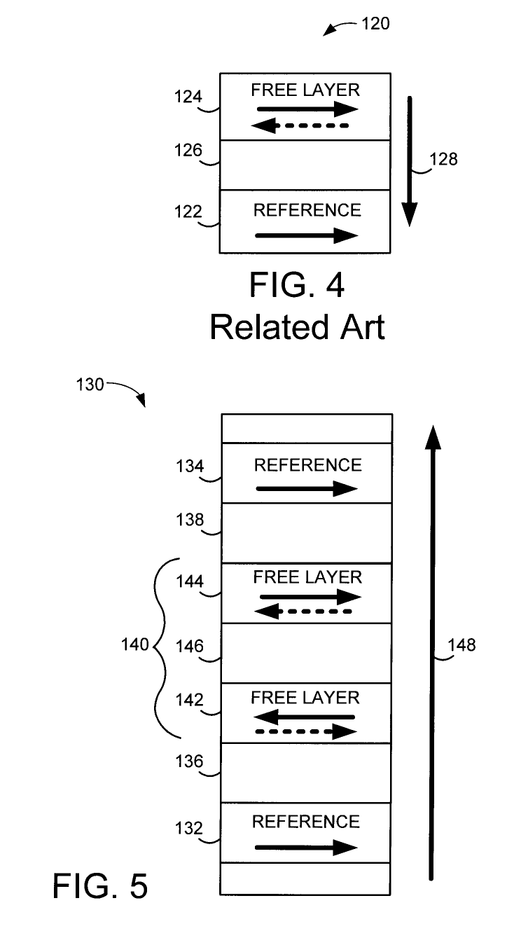

FIG. 4 shows a memory cell construction in accordance with the related art. The memory cell in FIG. 4 has a spin-torque transfer random access memory (STRAM) configuration with a magnetic tunneling junction (MTJ) 120. The MTJ 120 includes a fixed reference layer 122 and a programmable free layer 124 (recording layer) separated by an intervening tunneling (barrier) layer 126.

The reference layer 124 has a fixed magnetic orientation in a selected direction, as indicated by the associated arrow shown in FIG. 4. This fixed magnetic orientation can be established in a number of ways, such as via pinning to a separate magnet (not shown). The free layer 124 has a selectively programmable magnetic orientation that can be parallel (solid arrow) or anti-parallel (dotted arrow) with the selected direction of the reference layer 124.

A low resistance state for the MTJ 120 is achieved when the magnetization of the free layer 124 is oriented to be substantially in the same direction (parallel) as the magnetization of the reference layer 122. To orient the MTJ 120 in the parallel low resistance state, a write current passes through the MTJ 120 so that the magnetization direction of the reference layer 122 sets the magnetic orientation of the free layer 124. Since electrons flow in the direction opposite to the direction of current, the write current direction passes from the free layer 124 to the reference layer 122, so that the electrons travel from the reference layer 122 to the free layer 124. This programming input direction is represented at 128.

A high resistance state for the MTJ 120 is established in the anti-parallel orientation in which the magnetization direction of the free layer 124 is substantially opposite that of the reference layer 122. To orient the MTJ 120 in the anti-parallel resistance state, a write current passes through the MTJ 120 from the reference layer 122 to the free layer 124 so that spin-polarized electrons flow into the free layer 124. This programming input direction is opposite that of arrow 128.

A different logical state is assigned to each of the programmable resistances of the MTJ. In some embodiments, the low resistance, parallel state is used to represent a logical 0, and the high resistance, anti-parallel state is used to represent a logical 1. Additional programmed states can be used when the MTJ is configured to store multiple bits. For example, programmed resistances R1<R2<R3<R4 can be used to respectively store multi-bit values “00,” “01,” “10” and “11.”

While operable, STRAM configurations such as shown in FIG. 4 can be subjected to a number of limitations. It is known to spin polarize write currents to more easily induce magnetic precession and a switching of the recording layer's magnetization. The current necessary to switch the logical state of an MTJ can be written as:

$${J}_{c 0} = \frac{1}{η} ( \frac{2 e}{ℏ} ) α M t ( {H}_{K} + 2 π M + H ) \qquad [ 1 ]$$

where η is the spin polarization of the current, α is the damping constant, H_{K} and H are the anisotropy field and external field, and M is the saturation magnetization of the recording layer.

The recording layer often comprises ferromagnetic materials (e.g., NiFe or CoFeB) for which the in-plane anisotropy 2πM may be much larger than H_{K}. In such case, the switching current will be dominated by the in-plane anisotropy 2πM, while the thermal stability and long term data retention characteristics of the MTJ will be significantly controlled by the anisotropy field H_{K}.

It follows that conventional designs such as in FIG. 4 can be provided with relatively high in-plane anisotropy effects, which lead to relatively high current requirements to switch the programmed state (particularly in the anti-parallel orientation). At the same time, such devices can have relatively low uni-axial anisotropic fields which serve to stabilize the cell against thermal excitations and provides long term retention of the programmed state. These factors can provide a tradeoff, in that the device can be configured to have better long term data retention characteristics, but at the cost of requiring higher switching currents during operation.

Accordingly, various embodiments of the present invention are generally directed to a novel resistive sense memory structure and associated method for writing data thereto that overcomes these and other limitations of the prior art.

As explained below, various embodiments provide a resistive sense memory comprising a first reference layer with a fixed magnetic orientation in a selected direction coupled to a first tunneling barrier and a second reference layer with a fixed magnetic orientation in the selected direction coupled to a second tunneling barrier. A programmable recording structure is disposed between the first and second tunneling barriers, and includes first and second free layers.

A selected logic state is written to the resistive sense memory by applying a programming input to the memory, such as in the form of a selected write current therethrough. This programming input imparts complementary (opposing) first and second programmed magnetic orientations to the respective first and second free layers. Greater thermal stability and longer term data retention are achieved while reducing write current requirements to program a selected state. The complementary states of the first and second free layers can provide the recording structure with a net zero magnetic moment, further enhancing thermal stability and long term data retention, and reducing inter-cell interference.

FIG. 5 illustrates a construction for a resistive sense memory element 130 in accordance with some embodiments of the present invention. The element 130 includes first and second reference layers 132, 134. The reference layers 132, 134 have fixed magnetic orientations in a selected direction (as indicated by the associated arrows in FIG. 5).

The reference layers 132, 134 are coupled to respective first and second tunneling barriers 136, 138. A programmable recording structure 140 is disposed between the respective tunneling barriers 136, 138. The recording structure 140 includes first and second free (recording) layers 142, 144 separated by an intervening spacer layer 146. The spacer layer 146 allows the free layers 142 and 144 to have separate, complementary magnetization moments.

The recording structure 140 can be a synthetic antiferromagnetic (SAF) layer that antiferromagnetically couples the first and second recording layers 142, 144 to the spacer layer 146. Various techniques can be employed to antiferromagnetically couple the SAF including, but not limited to, interlayer coupling and static coupling that results in a weak coupling field so not to affect the switching current significantly.

In various embodiments of the present invention, the reference layers 132, 134 each comprise spin polarizing material that uniformly spins incoming current pulses, such as represented at 148. The reference layers 132, 134 have substantially the same magnetic moments and moment direction to reduce the amount of current necessary to induce precession in the recording structure 140.

The application of a programming input (e.g., write current) will operate to set a selected one of the first and second free layers 142, 144 to a first magnetic orientation, and will operate to set the other one of the first and second free layers 142, 144 to a second magnetic orientation opposite that of the first orientation. These complementary magnetization orientations are represented in FIG. 5 by the respective solid and dashed arrows, and one of these complementary magnetization orientations will be parallel with (i.e., in the same direction as) the fixed magnetization direction of the reference layers 132, 134.

By way of illustration, application of the write current 148 in FIG. 5 will generally operate to set the memory 130 to a high resistive state, with the magnetization orientations of the recording layers 142, 144 represented by the solid arrows (i.e., to the left in layer 142, and to the right in layer 144). The high resistance state can be characterized as an antiparallel relationship between the recording layer 142 and the reference layer 132, and can be sensed as discussed above in FIG. 3.

Application of a write current in the opposite direction (downwardly through the element 130 in FIG. 5) will result in the magnetization orientations of the recording layers 142, 144 as represented by the dashed arrows in FIG. 5. This low resistance state can be characterized as a parallel relationship between the recording layer 142 and the reference layer 132, and as before can be sensed as shown in FIG. 3.

The electrons in a given programming current will be spin polarized by the first encountered reference layer and will traverse the first encountered tunneling barrier to the recording structure 140, where the current will cause precession and subsequent switching of the magnetic moment of both recording layers 142, 144 depending on the initial magnetic moment of the first encountered recording layer. In other words, a spin polarized current will switch the magnetic moment of the recording structure and resistance state of the memory cell 130 if the current is large enough and the first recording layer is in the opposing magnetic moment direction initially.

While it is contemplated that the read sense currents can be directed so as to pass through the entire stack in FIG. 5, such is not necessarily required. The direction of sense current can also be selected as desired.

It will be appreciated by one skilled in the art that the multiple layers and zero net magnetic moment of the recording structure 140 provide high thermal stability with negligible increase in switching current due to the spin polarization of the reference layers 132, 134. The memory 130 is stable for an increased amount of time over prior art structures such as FIG. 4 due to the lack of static field being applied to adjacent memory cells and reduced interference.

The spin polarizing reference layers 132, 134 can be formed of various ferromagnetic materials with acceptable spin polarization ranges, such as but not limited to Co, Ni or Fe and associated alloys. The recording layers 142, 144 can comprise ferromagnetic materials with acceptable anisotropy, including but not limited to Co, Ni or Fe and associated alloys.

The spacer layer 146 can be constructed as a conductive non-ferromagnetic material such as but not limited to Ta, Cu, Ru or Au. The tunneling barrier layers 136, 138 can each be a tunneling insulator layer to facilitate reading of the programmed resistance state of the memory cell 130. In some embodiments, the total magneto-resistance ratio (MR) of the memory cell 130 is larger than 40%.

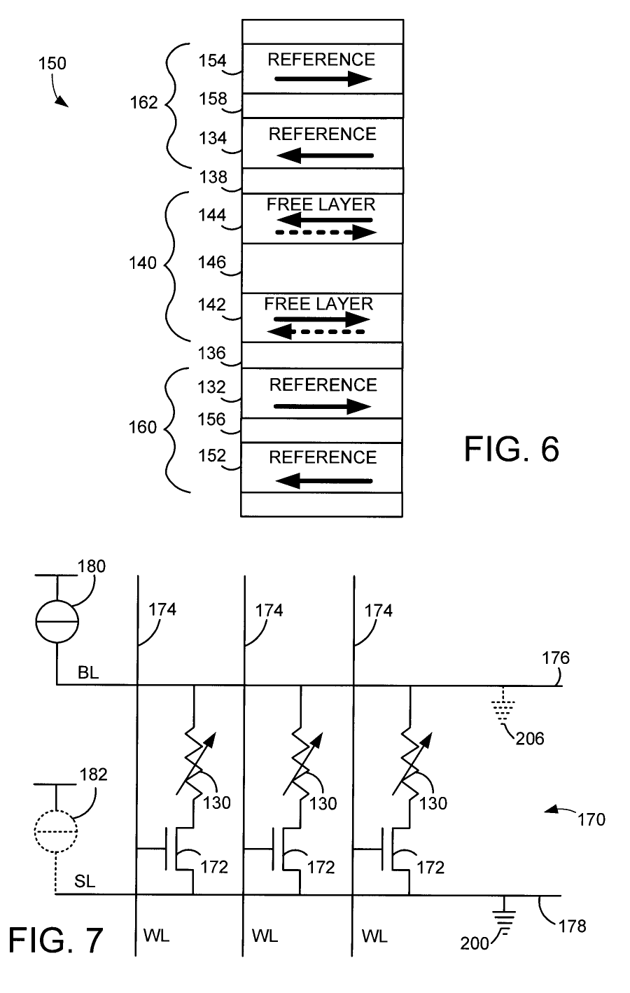

FIG. 6 shows an alternative construction for a resistive sense memory 150 in accordance with other embodiments of the present invention. The memory construction in FIG. 6 is similar to that in FIG. 5, and like reference numerals have been used for similar components. FIG. 6 additionally includes third and fourth reference layers 152, 154 coupled to associated tunneling barriers 156, 158. The reference layers 152, 154 serve as secondary reference layers. In some embodiments, the reference layers 152, 154 have a common direction of magnetic orientation that is opposite the common direction of magnetic orientation of reference layers 132, 134, as shown.

The respective sets of reference layers and tunneling barriers can be characterized as forming opposing reference structures 160, 162. As before, the recording structure 140 is disposed between these reference structures 160, 162, and generally operates as described above.

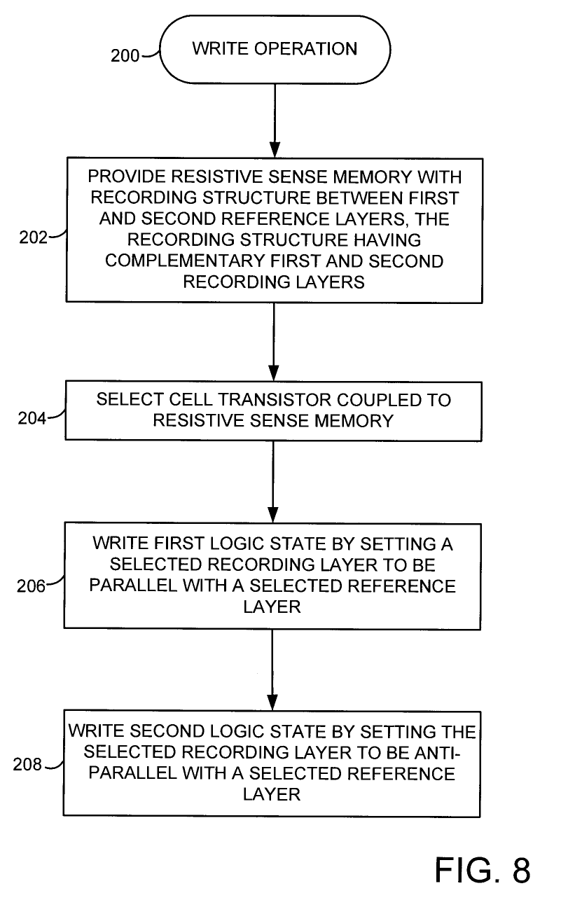

FIG. 7 illustrates an array 170 of resistive sense memory cells 130 from FIG. 5. It will be appreciated that the array 170 can be alternatively configured with cells 150 from FIG. 6.

Each cell 130 is coupled to a cell switching device 172, such as a metal oxide semiconductor field effect transistor (MOSFET). The transistors 172 are respectively selectable by corresponding word lines, WL 174. Asserting a suitable voltage on a selected WL 174 places the associated cell into a conductive state, facilitating passage of current between a bit line, BL 176 and a source line, SL 178. Write current drivers 180, 182 are respectively coupled to apply the requisite programming inputs (e.g., write currents) in the appropriate directions through the cells.

FIG. 10 shows a flow diagram of an exemplary write operation routine 200 performed in accordance with various embodiments of the present invention. The routine 200 begins at step 202 by providing an array such as 170 with resistive sense memories such as 130 or 150. Generally, each resistive sense memory has a recording structure such as 140 between first and second reference layers such as 132, 134. The recording structure includes complementary first and second recording layers, such as 142, 144.

A transistor such as 172 coupled to the resistive sense memory is asserted at step 204. A first programming state is written to the resistive sense memory at step 206, and a second programming state is written to the resistive sense memory at step 208. These respective programming states are obtained by flowing suitable write currents in opposing directions through the resistive sense memory as shown in FIG. 7, and set the magnetization orientations of the recording layers with respect to the magnetization orientations of the reference layers accordingly.

As will be appreciated by one skilled in the art, the various embodiments disclosed herein provide advantages in both memory cell efficiency and reliability due to the increased thermal stability and decreased static interference. The utilization of improved thermal retention of the resistive sense memory cell improves accuracy of writing data. Moreover, the improved thermal stability of the memory cell that corresponds with low switching power requirements due to spin polarized switching current improves the performance of the memory cell. It will be appreciated that the various embodiments discussed herein have numerous potential applications and are not limited to a certain field of electronic media or type of data storage devices.

It is to be understood that even though numerous characteristics and advantages of various embodiments of the present invention have been set forth in the foregoing description, together with details of the structure and function of various embodiments of the invention, this detailed description is illustrative only, and changes may be made in detail, especially in matters of structure and arrangements of parts within the principles of the present invention to the full extent indicated by the broad general meaning of the terms in which the appended claims are expressed.

What is claimed is:

1. A resistive sense memory comprising:
a first reference layer with a fixed magnetic orientation in a selected direction coupled to a first tunneling barrier;
a second reference layer with a fixed magnetic orientation in the selected direction coupled to a second tunneling barrier; and
a recording structure disposed between the first and second tunneling barriers comprising first and second free layers configured to have complementary first and second programmed magnetic orientations responsive to a programming input.

2. The resistive sense memory of claim 1, wherein a programming input to place the resistive sense memory into a lower programmed resistance state orients the first programmed magnetic orientation in the selected direction and orients the second programmed magnetic orientation in a direction opposite the selected direction.
zero net magnetic moment

3. The resistive sense memory of claim 1, wherein the recording structure provides zero net magnetic moment.

4. The resistive sense memory of claim 1, wherein the first and second free layers are characterized as ferromagnetic layers.

5. The resistive sense memory of claim 4, wherein the ferromagnetic layers are selectively programmed to have opposing magnetic moments responsive to the programming input.

6. The resistive sense memory of claim 4, wherein the ferromagnetic layers are statically coupled to a spacer layer.

7. The resistive sense memory of claim 1, wherein the recording structure and reference layers comprise synthetic antiferromagnetic (SAF) layers.

8. The resistive sense memory of claim 1, wherein the first and second reference layers comprise spin polarizing material.

9. The resistive sense memory of claim 1, wherein the reference layers are fixed ferromagnetic layers.

10. The resistive sense memory of claim 1, further comprising:
a third reference layer with a fixed magnetic orientation in a second selected direction coupled to a third tunneling barrier;
a fourth reference layer with a fixed magnetic orientation in the second selected direction coupled to a fourth tunneling barrier.

11. A method comprising:
providing a resistive sense memory comprising a first reference layer with a fixed magnetic orientation in a selected direction coupled to a first tunneling barrier, a second reference layer with a fixed magnetic orientation in the selected direction coupled to a second tunneling barrier, and a recording structure disposed between the first and second tunneling barriers comprising first and second free layers; and
writing a selected logic state to the resistive sense memory by applying a programming input to impart complementary first and second programmed magnetic orientations to the respective first and second free layers.

12. The method of claim 11, wherein the programming input of the writing step comprises passing a write current through the resistive sense memory in a direction from the first reference layer to the second reference layer to place the resistive sense memory into a lower programmed resistance state that orients the first programmed magnetic orientation in the selected direction and orients the second programmed magnetic orientation in a direction opposite the selected direction.

13. The method of claim 11, wherein the programming input of the writing step comprises passing a write current through the resistive sense memory in a direction from the second reference layer to the first reference layer to place the resistive sense memory into a higher programmed resistance state that orients the second programmed magnetic orientation in the selected direction and orients the first programmed magnetic orientation in a direction opposite the selected direction.

14. The method of claim 11, wherein the recording structure provides zero net magnetic moment.

15. The method of claim 14, wherein the first and second free layers are characterized as ferromagnetic layers with opposing magnetic moments.

16. The method of claim 14, wherein the ferromagnetic layers are statically coupled to a spacer layer.

17. The method of claim 11, wherein the recording structure and reference layers comprise synthetic antiferromagnetic (SAF) layers.

18. The method of claim 11, wherein the first and second reference layers comprise spin polarizing material.

19. The method of claim 11, wherein the reference layers are fixed ferromagnetic layers.

20. The method of claim 11, wherein the resistive sense memory of the providing step further comprises a third reference layer with a fixed magnetic orientation in a second selected direction coupled to a third tunneling barrier, and a fourth reference layer with a fixed magnetic orientation in the second selected direction coupled to a fourth tunneling barrier.
